(19) United States
(12) Patent Application Publication
(10) Pub. No.: US 2026/0282978 A1
(43) Pub. Date: Sep. 17, 2026

(54) SEMICONDUCTOR DEVICE

(71) Applicant: Mitsubishi Electric Corporation, Tokyo (JP)

(72) Inventors: Hiroyuki HARADA, Chiyoda-ku, Tokyo (JP); Seiji OKA, Chiyoda-ku, Tokyo (JP); Hidetoshi ISHIBASHI, Chiyoda-ku, Tokyo (JP)

(73) Assignee: Mitsubishi Electric Corporation, Tokyo (JP)

(21) Appl. No.: 18/878,162

(22) PCT Filed: Jun. 28, 2022
(86) PCT No.: PCT/JP2022/025742

§ 371 Date: Dec. 23, 2024

(51) Int. Cl. H10W 70/652; H10W 76/134; H10W 76/63; H10W 76/67; H10W 90/00

(52) U.S. Cl. CPC H10W 70/6528; H10W 76/134; H10W 76/63; H10W 76/67; H10W 90/734; H10W 90/753; H10W 90/755; H10W 90/757

(57) ABSTRACT

A semiconductor device includes an insulation layer and a first electrode pattern. The first electrode pattern includes a first body portion and a first step portion. The first body portion has a first surface facing the insulation layer, a second surface located opposite to the first surface, and a first side surface. The first step portion has a third surface facing the insulation layer, and a first step surface located opposite to the third surface. A boundary between the second surface and the first side surface is defined as a first boundary. A boundary between the first side surface and the first step surface is defined as a second boundary. In a cross section perpendicular to the second surface, a length of the first side surface is longer than a length of a line segment connecting the first boundary and the second boundary.

### TECHNICAL FIELD

The present disclosure relates to a semiconductor device.

### BACKGROUND ART

A semiconductor element dealing with a high voltage or a high current is generally called a power semiconductor element. Normally, a path of a current flowing through the power semiconductor element extends in the thickness direction of the element. Examples of the power semiconductor element are, for example, an insulated gate bipolar transistor (IGBT), a metal oxide semiconductor field effect transistor (MOSFET), a bipolar transistor, a diode, and the like, A device including an insulation substrate having a power semiconductor element mounted thereon and packaged by a sealing member is called a semiconductor device,

Semiconductor devices are used in a wide range of fields such as industrial equipment, automobiles, and railways. In recent years, as devices equipped with semiconductor devices have been enhanced in performance, the rated voltage and the rated current of the semiconductor device have increased, and also, the operation temperature range of the semiconductor device has expanded (to a higher temperature and a lower temperature). In other words, there is an increasing demand for higher performance and higher reliability of semiconductor devices. In order to satisfy this demand, the insulation substrate having a semiconductor element mounted thereon needs to be enhanced in heat dissipation performance and in reliability.

Japanese Patent Laying-Open No. 2004-296619 (PTL 1) discloses a method of manufacturing an insulation substrate for forming an electrode pattern having a side surface provided with a step portion by milling at least a part of a metal layer.

### CITATION LIST

### Patent Literature

PTL 1: Japanese Patent Laying-Open No. 2004-296619

### SUMMARY OF INVENTION

### Technical Problem

According to the insulation substrate manufactured by the manufacturing method disclosed in PTL 1, however, the side surface of the electrode pattern has a linear shape. Thus, when a heat cycle is applied, peeling between the electrode pattern and the insulation substrate can be suppressed by the step portion, but peeling may occur between the sealing member and the insulation substrate. This may lead to degradation in insulation performance of the semiconductor device.

The present disclosure has been made in view of the above-described situation, and an object thereof is to provide a semiconductor device capable of suppressing degradation in insulation performance that results from a heat cycle.

### Solution to Problem

A semiconductor device according to the present disclosure includes an insulation substrate, a semiconductor element, a case, and a sealing member. The insulation substrate includes an insulation layer and a first electrode pattern. The first electrode pattern is provided on the insulation layer. The semiconductor element is provided on the first electrode pattern. The case surrounds the insulation substrate. The sealing member covers each of the insulation substrate and the semiconductor element. The first electrode pattern includes a first body portion and a first step portion. The first step portion protrudes from the first body portion. The first body portion has a first surface, a second surface, and a first side surface. The first surface faces the insulation layer. The second surface is located opposite to the first surface. The second surface faces the semiconductor element. The first side surface is contiguous to the second surface. The first step portion has a third surface and a first step surface. The third surface is contiguous to the first surface. The third surface faces the insulation layer. The first step surface is located opposite to the third surface. The first step surface is contiguous to the first side surface. In a cross section perpendicular to the second surface, the first side surface has a curved shape. In the cross section perpendicular to the second surface, a boundary between the second surface and the first side surface is defined as a first boundary. In the cross section perpendicular to the second surface, a boundary between the first side surface and the first step surface is defined as a second boundary. A length of a line segment connecting the first boundary and the second boundary in the cross section perpendicular to the second surface is defined as a first length. A length of the first side surface in the cross section perpendicular to the second surface is longer than the first length.

### Advantageous Effects of Invention

According to the present disclosure, peeling between the sealing member and the insulation substrate can be suppressed by an anchor effect between the first side surface and the sealing member while improving the force of joining between the first electrode pattern and the insulation layer by the first step portion of the first electrode pattern. Thereby, it is possible to provide a semiconductor device capable of suppressing degradation in insulation performance that results from a heat cycle.

### BRIEF DESCRIPTION OF DRAWINGS

FIG. 1 is a schematic cross-sectional view showing a configuration of a semiconductor device according to a first embodiment.

FIG. 2 is an enlarged schematic cross-sectional view showing a region II in FIG. 1 but not showing a sealing member for convenience of illustration.

FIG. 3 is an enlarged schematic cross-sectional view showing a step of joining a metal plate to an insulation layer.

FIG. 4 is an enlarged schematic cross-sectional view showing a step of cutting the metal plate.

FIG. 5 is an enlarged schematic cross-sectional view showing a step of printing an etching resist on the metal plate.

FIG. 6 is an enlarged schematic cross-sectional view showing a configuration of a semiconductor device according to a modification of the first embodiment.

FIG. 7 is a schematic cross-sectional view showing a configuration of a semiconductor device according to a second embodiment.

FIG. 8 is a schematic cross-sectional view showing a configuration of a semiconductor device according to a third embodiment.

FIG. 9 is an enlarged schematic cross-sectional view of a region IX in FIG. 8.

FIG. 10 is an enlarged schematic cross-sectional view showing a configuration of a semiconductor device according to a modification of the third embodiment.

### DESCRIPTION OF EMBODIMENTS

Hereinafter, embodiments of the present disclosure will be described with reference to the accompanying drawings. In the drawings described below, the same or corresponding portions are denoted by the same reference characters, and the description thereof will not be repeated.

### First Embodiment

### (Configuration of Semiconductor Device)

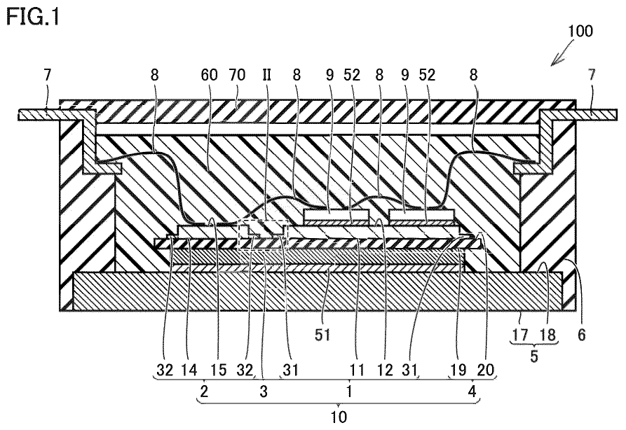

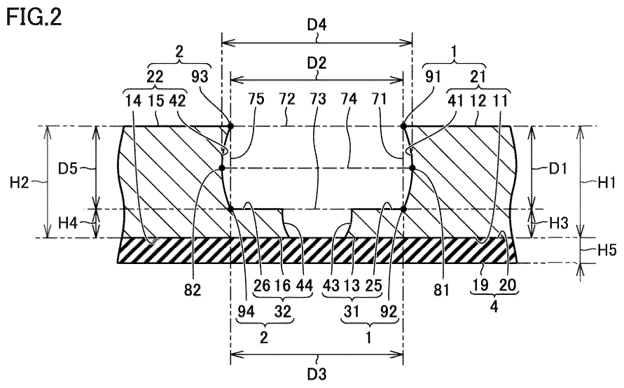

The configuration of a semiconductor device 100 will be hereinafter described with reference to FIGS. 1 and 2. As shown in FIG. 1, semiconductor device 100 mainly includes a base plate 5, an insulation substrate 10, a first joining portion 51, a semiconductor element 9, a second joining portion 52, a wire 8, a terminal 7, a case 6, a lid 70, and a sealing member 60.

Base plate 5 forms a bottom surface of semiconductor device 100. In other words, base plate 5 is a bottom plate of semiconductor device 100. Insulation substrate 10 is located on base plate 5. Insulation substrate 10 and base plate 5 are joined to each other, for example, by first joining portion 51. Semiconductor element 9 is located on insulation substrate 10. Semiconductor element 9 and insulation substrate 10 are joined to each other, for example, by second joining portion 52. Case 6 is combined with base plate 5. Case 6 forms a side surface of semiconductor device 100. Terminal 7 is located on case 6. Lid 70 is located on case 6. Lid 70 and case 6 are bonded to each other, for example, by an adhesive (not shown). Sealing member 60 fills a region surrounded by base plate 5, case 6, and lid 70. Wire 8 serves as a portion through which semiconductor element 9 is electrically connected to a device (not shown) external to semiconductor device 100.

Base plate 5 has, for example, a flat plate shape. Base plate 5 has a seventh surface 17 and an eighth surface 18. Seventh surface 17 is a bottom surface of semiconductor device 100. Eighth surface 18 is located opposite to seventh surface 17. Base plate 5 is made, for example, of copper. Insulation substrate 10 faces eighth surface 18 of base plate 5. Insulation substrate 10 includes an insulation layer 4, a first electrode pattern 1, a second electrode pattern 2, and a third electrode pattern 3.

Third electrode pattern 3 faces eighth surface 18 of base plate 5. Third electrode pattern 3 is made, for example, of copper. Third electrode pattern 3 and base plate 5 are joined to each other, for example, by first joining portion 51. First joining portion 51 is, for example, solder. First joining portion 51 may be made, for example, of silver or a silver alloy.

Insulation layer 4 is located on third electrode pattern 3. Insulation layer 4 has a ninth surface 19 and a tenth surface 20. Ninth surface 19 faces third electrode pattern 3. Insulation layer 4 is in contact at ninth surface 19 with third electrode pattern 3. Third electrode pattern 3 is provided on ninth surface 19 of insulation layer 4, for example, by a direct joining method, a brazing material joining method, a molten metal joining method, or a plating method. Tenth surface 20 is located opposite to ninth surface 19.

Insulation layer 4 insulates semiconductor element 9 from base plate 5. Insulation layer 4 desirably has heat dissipation properties. Insulation layer 4 is made of ceramic such as aluminum oxide (Al₂O₃), silicon dioxide (SiO₂), aluminum nitride (AlN), boron nitride (BN), or silicon nitride (Si₃N₄).

First electrode pattern 1 is provided on insulation layer 4. First electrode pattern 1 is provided on insulation layer 4, for example, by a direct joining method, a brazing material joining method, a molten metal joining method, or a plating method. First electrode pattern 1 faces insulation layer 4. First electrode pattern 1 is made, for example, of copper. First electrode pattern 1 has a first surface 11 and a second surface 12.

First surface 11 faces insulation layer 4. First electrode pattern 1 is in contact at first surface 11, for example, with insulation layer 4. First electrode pattern 1 may be joined at first surface 11 to insulation layer 4 with a joining material (not shown) interposed therebetween. Second surface 12 is located opposite to first surface 11.

Second electrode pattern 2 is provided on insulation layer 4. Second electrode pattern 2 faces tenth surface 20 of insulation layer 4. Second electrode pattern 2 is provided on insulation layer 4, for example, by a direct joining method, a brazing material joining method, a molten metal joining method, or a plating method. Second electrode pattern 2 is located apart from first electrode pattern 1. Second electrode pattern 2 is made, for example, of copper. Second electrode pattern 2 has a fourth surface 14 and a fifth surface 15.

Fourth surface 14 faces insulation layer 4, Second electrode pattern 2 is in contact at fourth surface 14, for example, with insulation layer 4. Second electrode pattern 2 may be joined at fourth surface 14 to insulation layer 4 with a joining material (not shown) interposed therebetween. Fifth surface 15 is located opposite to fourth surface 14. The cross section shown in FIG. 1 is a cross section perpendicular to second surface 12. Specifically, the cross section shown in FIG. 1 is a cross section perpendicular to second surface 12 and intersecting with each of first electrode pattern 1 and second electrode pattern 2.

Semiconductor element 9 is provided on first electrode pattern 1. Semiconductor element 9 faces second surface 12 of first electrode pattern 1. Semiconductor element 9 and first electrode pattern 1 are joined to each other by second joining portion 52. From a different point of view, each of semiconductor element 9 and first electrode pattern 1 is in contact with second joining portion 52. Second surface 12 is located apart from semiconductor element 9. Second joining portion 52 is, for example, solder. Second joining portion 52 may be made, for example, of silver or a silver alloy. The number of semiconductor elements 9 is, for example, two. Two semiconductor elements 9 are electrically connected to each other through wire 8.

Semiconductor element 9 is a wide bandgap semiconductor made, for example, of a silicon carbide (SiC)-based or a gallium nitride (GaN)-based material, diamond, or the like. Note that a wide gap semiconductor is a semiconductor wider in band gap than silicon (Si). Semiconductor element 9 is, for example, a power semiconductor element that is operated at a temperature reaching 150° C. or higher. Specifically, semiconductor element 9 is a semiconductor element such as a MOSFET for controlling a high current. Semiconductor element 9 may be a freewheeling diode.

Case 6 has an annular shape. Case 6 surrounds insulation substrate 10. Case 6 is preferably made of a material that does not thermally deform within the operation temperature range of semiconductor device 100. Case 6 is preferably made of a material having an insulating property. Specifically, case 6 is preferably made of a resin material having a high thermal softening point. More specifically, case 6 is made, for example, of a poly phenylene sulfide (PPS) resin.

Lid 70 isolates the inside of semiconductor device 100 from the outside thereof. Lid 70 serves to prevent dust and the like from intruding into semiconductor device 100. Terminal 7 is located between lid 70 and case 6. Terminal 7 may be sandwiched between case 6 and lid 70. A part of terminal 7 is exposed to the outside of semiconductor device 100. Terminal 7 is made, for example, of copper.

Wire 8 electrically connects terminal 7 and semiconductor element 9. Wire 8 electrically connects semiconductor element 9 and second electrode pattern 2. Wire 8 electrically connects second electrode pattern 2 and terminal 7. Wire 8 has a linear shape. Wire 8 has, for example, a circular cross section. Wire 8 is made, for example, of gold or aluminum.

Sealing member 60 covers each of insulation substrate 10, semiconductor element 9, and wire 8. Sealing member 60 insulates insulation substrate 10, semiconductor element 9, and wire 8 from one another. Sealing member 60 is in contact with each of terminal 7, case 6, and base plate 5. Sealing member 60 is located apart from lid 70. Sealing member 60 is made of a resin having a prescribed elastic modulus and heat resistance property. Specifically, sealing member 60 is made, for example, of an epoxy resin. Sealing member 60 may be made of a resin having an insulating property and adhesiveness. Specifically, sealing member 60 may be made, for example, of a silicone resin.

As shown in FIG. 2, first electrode pattern 1 includes a first body portion 21 and a first step portion 31. First step portion 31 protrudes from first body portion 21. Specifically, first step portion 31 protrudes from first body portion 21 in the direction parallel to first surface 11,

First body portion 21 forms each of first surface 11 and second surface 12 of first electrode pattern 1. First body portion 21 has a first side surface 41. First side surface 41 is contiguous to second surface 12. First side surface 41 faces second electrode pattern 2. First side surface 41 is located apart from second electrode pattern 2. In the cross section perpendicular to second surface 12, first side surface 41 has a curved shape. In the cross section perpendicular to second surface 12, first side surface 41 may have an arc shape. In the cross section perpendicular to second surface 12, first side surface 41 is recessed, for example, inwardly of first body portion 21.

First step portion 31 has a third surface 13, a first step surface 25, and a first step side surface 43. Third surface 13 is contiguous to first surface 11 of first body portion 21. Third surface 13 forms a part of the bottom surface of first electrode pattern 1. Third surface 13 faces insulation layer 4. First electrode pattern 1 is in contact at third surface 13, for example, with insulation layer 4. First electrode pattern 1 may be joined at third surface 13 to insulation layer 4 with a joining material (not shown) interposed therebetween. Third surface 13 extends in the direction in which first surface 11 extends.

First step surface 25 is located opposite to third surface 13. First step surface 25 is contiguous to first side surface 41. First step surface 25 has, for example, a planar shape. First step surface 25 extends, for example, in the direction parallel to first surface 11. First step surface 25 is located between first surface 11 and second surface 12 in a direction perpendicular to second surface 12.

First step side surface 43 is contiguous to each of third surface 13 and first step surface 25. First step side surface 43 faces second electrode pattern 2. First step side surface 43 is located apart from second electrode pattern 2. First step side surface 43 is located on the outer side of first electrode pattern 1 with respect to first side surface 41. In the cross section perpendicular to second surface 12, first step side surface 43 has, for example, a curved shape. In the cross section perpendicular to second surface 12, first step side surface 43 may have an arc shape. In the cross section perpendicular to second surface 12, first step side surface 43 is recessed, for example, inwardly of first body portion 21.

As shown in FIG. 2, in the cross section perpendicular to second surface 12, a boundary between second surface 12 and first side surface 41 is defined as a first boundary 91. In the cross section perpendicular to second surface 12, a boundary between first side surface 41 and first step surface 25 is defined as a second boundary 92. In the cross section perpendicular to second surface 12, a line segment connecting first boundary 91 and second boundary 92 is defined as a first line segment 71. First line segment 71 may extend in the direction perpendicular to second surface 12. The length of first line segment 71 is defined as a first length D1. The length of first side surface 41 in the cross section perpendicular to second surface 12 is longer than first length D1. In the cross section perpendicular to second surface 12, the length of first side surface 41 is a distance along first side surface 41 from first boundary 91 to second boundary 92.

Second electrode pattern 2 includes a second body portion 22 and a second step portion 32. Second step portion 32 protrudes from second body portion 22. Specifically, second step portion 32 protrudes from second body portion 22 in the direction parallel to fourth surface 14. Note that the cross section shown in FIGS. 1 and 2 is a cross section perpendicular to second surface 12 and intersecting with each of first step portion 31 and second step portion 32.

Second body portion 22 forms each of fourth surface 14 and fifth surface 15 of second electrode pattern 2. Second body portion 22 has a second side surface 42. Second side surface 42 is contiguous to fifth surface 15. Second side surface 42 faces first side surface 41 of first electrode pattern 1. Second side surface 42 is located apart from first side surface 41. In the cross section perpendicular to second surface 12, second side surface 42 has a curved shape. In the cross section perpendicular to second surface 12, second side surface 42 may have an are shape. In the cross section perpendicular to second surface 12, second side surface 42 is recessed, for example, inwardly of second body portion 22.

Second step portion 32 has a sixth surface 16, a second step surface 26, and a second step side surface 44. Sixth surface 16 is contiguous to fourth surface 14 of second body portion 22. Sixth surface 16 forms a part of the bottom surface of second electrode pattern 2. Sixth surface 16 faces insulation layer 4. Second electrode pattern 2 is in contact at sixth surface 16, for example, with insulation layer 4. Second electrode pattern 2 may be joined at sixth surface 16 to insulation layer 4 with a joining material (not shown) interposed therebetween. Sixth surface 16 extends in the direction in which fourth surface 14 extends.

Second step surface 26 is located opposite to sixth surface 16. Second step surface 26 is contiguous to second side surface 42. Second step surface 26 has, for example, a planar shape. Second step surface 26 extends, for example, in the direction parallel to fourth surface 14. Second step surface 26 is located between fourth surface 14 and fifth surface 15 in the direction perpendicular to second surface 12,

Second step side surface 44 is contiguous to each of sixth surface 16 and second step surface 26. Second step side surface 44 faces first step side surface 43 of first electrode pattern 1. Second step side surface 44 is located apart from first step side surface 43. Second step side surface 44 is located on the outer side of second electrode pattern 2 with respect to second side surface 42. In the cross section perpendicular to second surface 12, second step side surface 44 has, for example, a curved shape. In the cross section perpendicular to second surface 12, second step side surface 44 may have an are shape. In the cross section perpendicular to second surface 12, second step side surface 44 is recessed, for example, inwardly of second body portion 22.

As shown in FIG. 2, in the cross section perpendicular to second surface 12, a boundary between fifth surface 15 and second side surface 42 is defined as a third boundary 93. In the cross section perpendicular to second surface 12, a boundary between second side surface 42 and second step surface 26 is defined as a fourth boundary 94. In the cross section perpendicular to second surface 12, a line segment connecting third boundary 93 and fourth boundary 94 is defined as a fifth line segment 75. Fifth line segment 75 may extend in the direction perpendicular to second surface 12. The length of fifth line segment 75 is defined as a fifth length D5. The length of second side surface 42 in the cross section perpendicular to second surface 12 is longer than fifth length D5. In the cross section perpendicular to second surface 12, the length of second side surface 42 is a distance along second side surface 42 from third boundary 93 to fourth boundary 94.

As shown in FIG. 2, in the cross section perpendicular to second surface 12, a line segment connecting first boundary 91 and third boundary 93 is defined as a second line segment 72. Second line segment 72 extends, for example, in a direction in which second surface 12 extends and in a direction extending from first electrode pattern 1 toward second electrode pattern 2. The length of second line segment 72 is defined as a second length D2.

In the cross section perpendicular to second surface 12, a line segment connecting second boundary 92 and fourth boundary 94 is defined as a third line segment 73. Third line segment 73 extends, for example, in a direction parallel to second surface 12 and in a direction extending from first electrode pattern 1 toward second electrode pattern 2. Third line segment 73 may be substantially parallel to second line segment 72. The length of third line segment 73 is defined as a third length D3. Third length D3 may be substantially the same as second length D2. Third length D3 may be longer than second length D2.

In the cross section perpendicular to second surface 12, an intermediate point of first side surface 41 is defined as a first intermediate point 81. In the direction perpendicular to second surface 12, the distance between first boundary 91 and first intermediate point 81 is equal to the distance between second boundary 92 and first intermediate point 81. In the cross section perpendicular to second surface 12, an intermediate point of second side surface 42 is defined as a second intermediate point 82. In the direction perpendicular to second surface 12, the distance between third boundary 93 and second intermediate point 82 is equal to the distance between fourth boundary 94 and second intermediate point 82.

In the cross section perpendicular to second surface 12, a line segment connecting first intermediate point 81 and second intermediate point 82 is defined as a fourth line segment 74. Fourth line segment 74 may be substantially parallel to second line segment 72. In the direction perpendicular to second surface 12, fourth line segment 74 is located between second line segment 72 and third line segment 73. The length of fourth line segment 74 is defined as a fourth length D4. Fourth length D4 is longer than each of second length D2 and third length D3.

As shown in FIG. 2, the thickness of first electrode pattern 1 in the direction perpendicular to second surface 12 is defined as a first thickness H1. First thickness H1 corresponds to a distance between first surface 11 and second surface 12 in the direction perpendicular to second surface 12. First thickness H1 is, for example, 0.3 mm or more and 5 mm or less. First thickness H1 may be, for example, 0.5 mm or more.

The thickness of second electrode pattern 2 in the direction perpendicular to second surface 12 is defined as a second thickness H2. Second thickness H2 corresponds to a distance between fourth surface 14 and fifth surface 15 in the direction perpendicular to second surface 12. Second thickness H2 is, for example, 0.3 mm or more and 5 mm or less. Second thickness H2 may be, for example, 0.5 mm or more. Second thickness H2 may be substantially the same as first thickness H1.

The thickness of first step portion 31 in the direction perpendicular to second surface 12 is defined as a third thickness H3. Third thickness H3 corresponds to a distance between third surface 13 and first step surface 25 in the direction perpendicular to second surface 12. Third thickness H3 is, for example, 0.2 mm. Third thickness H3 is smaller than first thickness H1. Third thickness H3 is, for example, 0.1 times or more and 0.8 times or less as large as first thickness H1.

The thickness of second step portion 32 in the direction perpendicular to second surface 12 is defined as a fourth thickness H4. Fourth thickness H4 corresponds to a distance between sixth surface 16 and second step surface 26 in the direction perpendicular to second surface 12. Fourth thickness 1-14 is, for example, 0.2 mm. Fourth thickness H4 is smaller than second thickness H2. Fourth thickness H4 is, for example, 0.1 times or more and 0.8 times or less as large as second thickness H2. Fourth thickness H4 may be substantially the same as third thickness H3.

The thickness of insulation layer 4 in the direction perpendicular to second surface 12 is defined as a fifth thickness H5. Fifth thickness H5 corresponds to a distance between ninth surface 19 and tenth surface 20 in the direction perpendicular to second surface 12. Fifth thickness H5 is, for example, 0.2 mm. First thickness H1 is, for example, four times or more as large as fifth thickness H5. The lower limit of first thickness H1 is not particularly limited but, for example, may be six times or more as large as fifth thickness H5 or may be eight times or more as large as fifth thickness 115. The upper limit of first thickness H1 is not particularly limited but, for example, may be twenty times or less as large as fifth thickness H5 or may be ten times or less as large as fifth thickness 1-15.

Second thickness H2 is, for example, four times or more as large as fifth thickness H5. The lower limit of second thickness H2 is not particularly limited but, for example, may be six times or more as large as fifth thickness H5 or may be eight times or more as large as fifth thickness H5. The upper limit of second thickness H2 is not particularly limited but, for example, may be twenty times or less as large as fifth thickness H5 or may be ten times or less as large as fifth thickness H5.

Third thickness H3 is, for example, equal to or larger than one half of fifth thickness H5. The lower limit of third thickness H3 is not particularly limited but, for example, may be fifth thickness H5 or more, or may be twice or more as large as fifth thickness H5. The upper limit of third thickness H3 is not particularly limited but, for example, may be five times or less as large as fifth thickness H5 or may be four times or less as large as fifth thickness H5.

Fourth thickness H4 is, for example, equal to or larger than one half of fifth thickness H5. The lower limit of fourth thickness H4 is not particularly limited but, for example, may be fifth thickness H5 or more, or may be twice or more as large as fifth thickness H5. The upper limit of fourth thickness H4 is not particularly limited but, for example, may be five times or less as large as fifth thickness H5 or may be four times or less as large as fifth thickness H5.

### (Method of Forming Electrode Pattern)

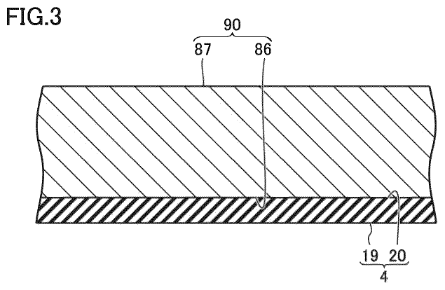

The following describes a method of forming first electrode pattern 1 and second electrode pattern 2 of semiconductor device 100 according to the first embodiment with reference to FIGS. 3 to 5. In the following description, first electrode pattern 1 and second electrode pattern 2 are also collectively simply referred to as an electrode pattern.

First, as shown in FIG. 3, a metal plate 90 is joined onto tenth surface 20 of insulation layer 4, for example, by a direct joining method. Metal plate 90 has an eleventh surface 86 and a twelfth surface 87. Eleventh surface 86 is in contact, for example, with insulation layer 4. Twelfth surface 87 is located opposite to eleventh surface 86.

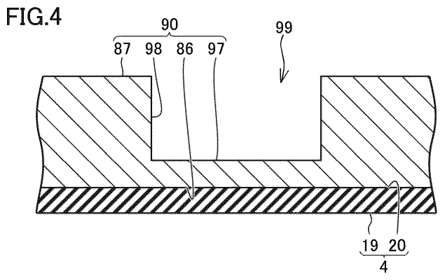

Then, as shown in FIG. 4, metal plate 90 is cut, for example, by milling and blasting. Thereby, a wall surface 98 and a bottom surface 97 are formed on metal plate 90. Wall surface 98 is contiguous to twelfth surface 87. Wall surface 98 extends in a direction perpendicular to twelfth surface 87. Bottom surface 97 is contiguous to wall surface 98. Wall surface 98 and bottom surface 97 provide a groove 99.

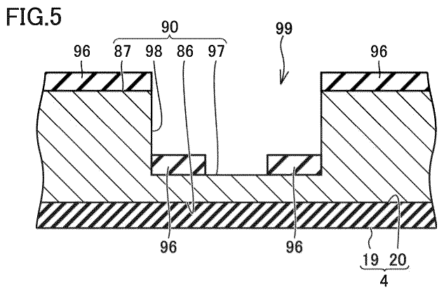

Then, as shown in FIG. 5, an etching resist 96 is printed on metal plate 90. Etching resist 96 is printed on each of a part of bottom surface 97 and twelfth surface 87. From a different point of view, twelfth surface 87 is covered with etching resist 96. A part of bottom surface 97 is exposed from etching resist 96. A part of wall surface 98 is exposed from etching resist 96.

Etching is performed on metal plate 90. As an etching solution, for example, a ferric chloride solution or the like is used. Etching is performed on each of bottom surface 97 and wall surface 98 of metal plate 90. A part of insulation layer 4 is exposed from metal plate 90. As described above, first electrode pattern 1 and second electrode pattern 2 (see FIGS. 1 and 2) are formed.

When the electrode pattern of insulation substrate 10 is formed only by etching, the time required for forming such an electrode pattern increases as compared with the case where the electrode pattern is formed by milling and etching. In particular, when the thickness of metal plate 90 is, for example, 0.5 mm or more, the time required for etching lengthens. Thus, when the etching solution is applied unevenly onto metal plate 90, the dimensions of the electrode pattern significantly vary. According to the method of forming an electrode pattern of semiconductor device 100 in the first embodiment, the electrode pattern is formed by milling and etching. Therefore, variations in dimensions of the electrode pattern can be reduced.

Further, when the electrode pattern of insulation substrate 10 is formed only by etching, the amount of the electrode pattern removed by etching increases from the bottom surface toward the top surface of the electrode pattern. In other words, the side surface of the electrode pattern is located to be closer to the inside of the electrode pattern from the bottom surface toward the top surface of the electrode pattern. Thus, second length D2 is longer than that in the case where the electrode pattern is formed by milling and etching. In other words, the ratio of the area of the top surface to the area of the bottom surface in the electrode pattern decreases. According to the method of forming an electrode pattern of semiconductor device 100 in the first embodiment, the ratio of the area of the top surface to the area of the bottom surface in the electrode pattern can be increased. In other words, the ratio of the area of the top surface of the electrode pattern to the area of tenth surface 20 of insulation layer 4 can be increased. Therefore, insulation substrate 10 can be reduced in size without changing the number of semiconductor elements 9 in semiconductor device 100. As a result, semiconductor device 100 can be reduced in size.

In the case where the electrode pattern is formed only by milling, insulation layer 4 may be damaged during processing of the electrode pattern in the vicinity of insulation layer 4. Thereby, the reliability of insulation substrate 10 may be decreased. According to the method of forming an electrode pattern of semiconductor device 100 in the first embodiment, the electrode pattern in the vicinity of insulation layer 4 is processed by etching. Thereby, a decrease in reliability of insulation substrate 10 can be suppressed.

The following describes functions and effects of semiconductor device 100 according to the first embodiment.

When a heat cycle is applied to semiconductor device 100, the components of semiconductor device 100 may peel off from each other due to a difference in coefficient of thermal expansion between these components. Specifically, first electrode pattern 1 may peel off from insulation layer 4 due to a difference in coefficient of thermal expansion between first electrode pattern 1 and insulation layer 4.

According to semiconductor device 100 in the first embodiment, first electrode pattern 1 includes first body portion 21 and first step portion 31. First step portion 31 protrudes from first body portion 21. First step portion 31 has third surface 13. Third surface 13 faces insulation layer 4. Thus, the area of joining between first electrode pattern 1 and insulation layer 4 can be increased. Further, an increase in thermal stress between first electrode pattern 1 and insulation layer 4 can be suppressed as compared with a case where the area of joining between first electrode pattern 1 and insulation layer 4 is increased by increasing the size of first body portion 21. Thereby, peeling between first electrode pattern 1 and insulation layer 4 can be suppressed.

Further, sealing member 60 may peel off from insulation substrate 10 due to a difference in coefficient of thermal expansion between sealing member 60 and insulation substrate 10. According to semiconductor device 100 in the first embodiment, first body portion 21 of first electrode pattern 1 has first side surface 41. In the cross section perpendicular to second surface 12, first side surface 41 has a curved shape. In the cross section perpendicular to second surface 12, the length of first side surface 41 is longer than the length of the line segment connecting first boundary 91 and second boundary 92. Thus, sealing member 60 is disposed to extend along first side surface 41. Thereby, an anchor effect is exerted onto sealing member 60. As to the anchor effect, for example, sealing member 60 flows into protrusions and recesses on first side surface 41 to bite into first side surface 41, to thereby achieve an effect of improving the force of joining between sealing member 60 and first electrode pattern 1 as the anchor effect.

Thus, peeling between sealing member 60 and insulation substrate 10 can be suppressed as compared with the case where first side surface 41 of first electrode pattern 1 has a linear shape. Thereby, in semiconductor device 100 according to the first embodiment, peeling between sealing member 60 and insulation substrate 10 can be suppressed while suppressing peeling between first electrode pattern 1 and insulation layer 4. This consequently makes it possible to suppress degradation in insulation performance of semiconductor device 100 that results from a heat cycle.

Semiconductor device 100 according to the first embodiment may include second electrode pattern 2. In the cross section perpendicular to second surface 12, the length (fourth length D4) of the line segment connecting first intermediate point 81 and second intermediate point 82 may be longer than each of the length (second length D2) of the line segment connecting first boundary 91 and third boundary 93; and the length (third length D3) of the line segment connecting second boundary 92 and fourth boundary 94. Thus, sealing member 60 is disposed so as to bite between first side surface 41 and second side surface 42. This enhances the anchor effect between sealing member 60 and each of first side surface 41 and second side surface 42. As a result, peeling off of sealing member 60 from insulation substrate 10 can be suppressed.

In order to improve the thermal diffusion performance in semiconductor device 100, the electrode pattern may be increased in thickness. As the electrode pattern is increased in thickness, the thermal stress between the electrode pattern and insulation layer 4 increases when a heat cycle is applied. Thus, first electrode pattern 1 is more likely to peel off. According to semiconductor device 100 in the first embodiment, in the direction perpendicular to second surface 12, the thickness of first electrode pattern 1 may be four times or more as large as the thickness of insulation layer 4. According to semiconductor device 100 in the first embodiment, even in insulation substrate 10 in which first electrode pattern 1 is thick as described above, peeling between insulation layer 4 and first electrode pattern 1 upon application of a heat cycle can be suppressed, and peeling between sealing member 60 and insulation substrate 10 upon application of a heat cycle can also be suppressed. This consequently makes it possible to suppress degradation in insulation performance of semiconductor device 100.

When the step portion of the electrode pattern is excessively thin, the contribution of the step portion to the force of joining between the electrode pattern and insulation layer 4 is correspondingly reduced. This reduces the effect of suppressing peeling between the electrode pattern and insulation layer 4. According to semiconductor device 100 in the first embodiment, the thickness of first step portion 31 may be equal to or larger than one half of the thickness of insulation layer 4. Thus, peeling between first electrode pattern 1 and insulation layer 4 can be more reliably suppressed.

When the step portion of the electrode pattern is excessively thick, the amount of thermal expansion in the step portion excessively increases. This may cause peeling between the electrode pattern and insulation layer 4. According to semiconductor device 100 in the first embodiment, the thickness of first step portion 31 may be five times or less as large as the thickness of insulation layer 4. Thus, peeling between first electrode pattern 1 and insulation layer 4 can be suppressed.

Further, when the ratio of the thickness of the step portion to the thickness of the electrode pattern is excessively high, the side surface of the body portion of the electrode pattern is excessively reduced in length, so that the anchor effect onto sealing member 60 is reduced. This may cause peeling between sealing member 60 and insulation substrate 10. According to semiconductor device 100 in the first embodiment, the thickness of first step portion 31 may be 0.8 times or less as large as the thickness of first electrode pattern 1. Thus, peeling between sealing member 60 and insulation substrate 10 can be suppressed.

### Modification of the First Embodiment

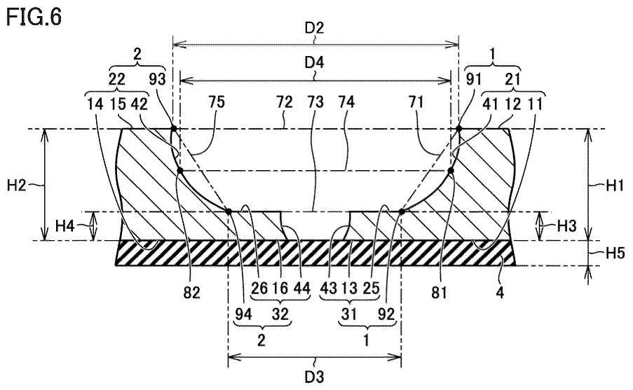

The following describes a configuration of a semiconductor device 100 according to a modification of the first embodiment with reference to FIG. 6. The schematic cross-sectional view shown in FIG. 6 corresponds to the schematic cross-sectional view shown in FIG. 2. As shown in FIG. 6, second length D2 may be longer than third length D3. In the cross section perpendicular to second surface 12, first boundary 91 may be located on the inner side of first electrode pattern 1 with respect to second boundary 92. In the cross section perpendicular to second surface 12, third boundary 93 may be located on the inner side of second electrode pattern 2 with respect to fourth boundary 94.

Second length D2 may be longer than fourth length D4. In the cross section perpendicular to second surface 12, first boundary 91 may be located on the inner side of first electrode pattern 1 with respect to first intermediate point 81. In the cross section perpendicular to second surface 12, third boundary 93 may be located on the inner side of second electrode pattern 2 with respect to second intermediate point 82.

In the above-described case, insulation layer 4 is made of ceramic. However, the configuration of semiconductor device 100 is not limited to the above-described configuration. Specifically, insulation layer 4 may be made, for example, of a resin cured product containing dispersed powder, in which case the powder is made, for example, of ceramic such as Al₂O₃, SiO₂, AlN, BN, or Si₃N₄. The powder may be made, for example, of diamond, silicon carbide, or boron oxide (B₂O₃), or may be made of a resin material such as a silicone resin or an acrylic resin. The shape of the powder is, for example, spherical. The shape of the powder may be a crushed shape, a granular shape, a scale-like shape, or an aggregate. The amount of the contained powder may be any amount as long as necessary heat dissipation property and insulation property can be achieved. Insulation layer 4 may be made of a resin cured product in which a ceramic plate is embedded.

The number of semiconductor elements 9 in semiconductor device 100 is not limited to two. The number of semiconductor elements 9 in semiconductor device 100 may be the number required according to the intended use of semiconductor device 100.

The materials of first electrode pattern 1, second electrode pattern 2, third electrode pattern 3, base plate 5, and terminal 7 are not particularly limited as long as they have necessary heat dissipation characteristics. Specifically, each of first electrode pattern 1, second electrode pattern 2, third electrode pattern 3, base plate 5, and terminal 7 may be made, for example, of a composite material of aluminum and iron, aluminum, or iron. Each of first electrode pattern 1, second electrode pattern 2, third electrode pattern 3, base plate 5, and terminal 7 may be made of a composite material such as a copper/invar/copper clad material, or may be made of a composite material of aluminum and silicon carbide (AlSiC). Each of first electrode pattern 1, second electrode pattern 2, third electrode pattern 3, base plate 5, and terminal 7 may be made of an alloy such as copper molybdenum (CuMo).

Each of first electrode pattern 1, second electrode pattern 2, third electrode pattern 3, base plate 5, and terminal 7 has a surface having a structure along which a necessary current and voltage can be supplied to the semiconductor element. Specifically, the surface of each of first electrode pattern 1, second electrode pattern 2, third electrode pattern 3, base plate 5, and terminal 7 is plated, for example, with nickel. The surface of each of first electrode pattern 1, second electrode pattern 2, third electrode pattern 3, base plate 5, and terminal 7 may be plated with gold or tin. The surface of each of first electrode pattern 1, second electrode pattern 2, third electrode pattern 3, base plate 5, and terminal 7 may be provided with minute irregularities. This makes it possible to improve the adhesiveness between sealing member 60 and each of first electrode pattern 1, second electrode pattern 2, third electrode pattern 3, base plate 5, and terminal 7.

Wire 8 may be, for example, a strip-shaped copper plate. In other words, the cross section of wire 8 may be, for example, rectangular. The number of wires 8 is, for example, four. The number of wires 8 may be the number required according to the current density and the like in semiconductor element 9.

The joining portion between wire 8 and each of semiconductor element 9, second electrode pattern 2, and terminal 7 has a structure through which a necessary current and voltage can be supplied to semiconductor element 9. Specifically, for example, each of semiconductor element 9, second electrode pattern 2, and terminal 7 may be joined to wire 8 through the use of melted copper, tin, or the like, or through the use of ultrasonic joining.

### Second Embodiment

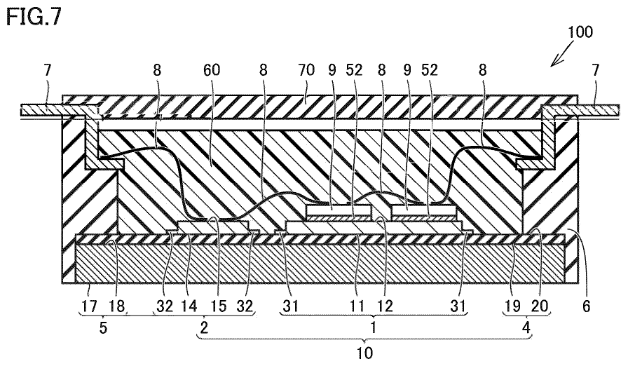

The following describes a configuration of a semiconductor device 100 according to the second embodiment with reference to FIG. 7. The configuration of semiconductor device 100 according to the second embodiment is different from the configuration of semiconductor device 100 according to the first embodiment mainly in that insulation layer 4 of insulation substrate 10 is made of an organic material, but is substantially identical in other points to the configuration of semiconductor device 100 according to the first embodiment. The following mainly describes the differences from the configuration of semiconductor device 100 according to the first embodiment. The schematic cross-sectional view shown in FIG. 7 corresponds to the schematic cross-sectional view shown in FIG. 1.

As shown in FIG. 7, insulation layer 4 of insulation substrate 10 may be joined to base plate 5. Ninth surface 19 of insulation layer 4 is in contact with eighth surface 18 of base plate 5. Insulation layer 4 and base plate 5 are joined to each other, for example, through joining by heating and pressurization (hot pressing). In other words, for example, a joining agent such as a brazing material is not used for joining insulation layer 4 to base plate 5. The area of ninth surface 19 of insulation layer 4 may be substantially the same as the area of eighth surface 18 of base plate 5.

Insulation layer 4 is made, for example, of an organic material. Specifically, insulation layer 4 may be made, for example, of an epoxy resin. Insulation layer 4 may be made of a thermosetting resin such as a polyimide resin, a silicone resin, or an acrylic resin. Insulation layer 4 may be made of an organic material, for example, formed of an epoxy resin or the like containing ceramic powder.

The following describes functions and effects of semiconductor device 100 according to the second embodiment.

As the area of insulation layer 4 is larger, insulation layer 4 is more likely to be influenced by warpage of semiconductor device 100 resulting from a load of a heat cycle. Thus, when the area of insulation layer 4 is excessively large, cracks may occur in insulation layer 4. According to the semiconductor device in the second embodiment, insulation layer 4 is made of an organic material. In general, organic materials are softer than ceramic. Thus, even when the area of insulation layer 4 is excessively large, occurrence of cracks in insulation layer 4 can be suppressed.

In the case where insulation layer 4 is made of an organic material, insulation layer 4 is brittle and easily wears out as compared with the case where insulation layer 4 is made of a ceramic material. Thus, in the case where the electrode pattern in the vicinity of insulation layer 4 is processed by milling or the like, insulation layer 4 may wear out, According to the semiconductor device in the present disclosure, etching is applied for forming the electrode pattern in the vicinity of insulation layer 4. Thus, wearing out of insulation layer 4 can be suppressed. As a result, a decrease in reliability of semiconductor device 100 can be suppressed.

### Third Embodiment

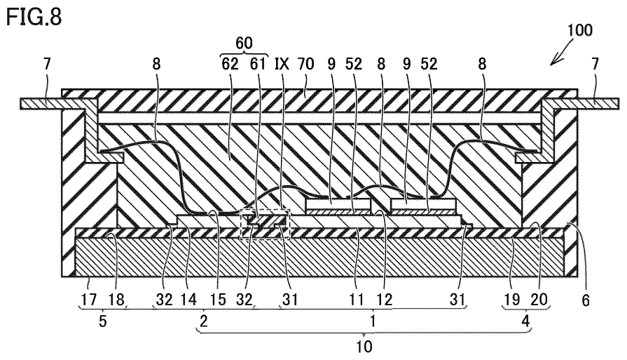

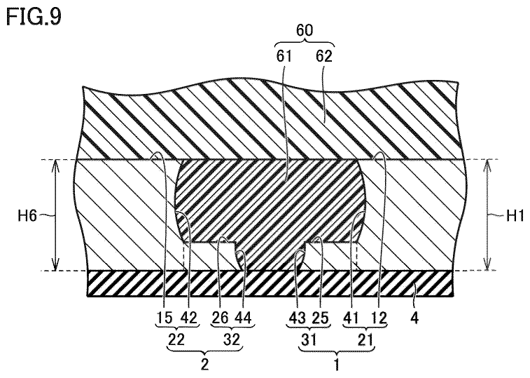

The following describes a configuration of a semiconductor device 100 according to the third embodiment with reference to FIGS. 8 and 9. The configuration of semiconductor device 100 according to the third embodiment is different from the configuration of semiconductor device 100 according to the second embodiment mainly in that sealing member 60 includes a first sealing portion 61 and a second sealing portion 62, but is substantially identical in other points to the configuration of semiconductor device 100 according to the second embodiment. The following mainly describes the differences from the configuration of semiconductor device 100 according to the second embodiment. The schematic cross-sectional view shown in FIG. 8 corresponds to the schematic cross-sectional view shown in FIG. 1.

As shown in FIGS. 8 and 9, sealing member 60 includes first sealing portion 61 and second sealing portion 62. First sealing portion 61 is located between first electrode pattern 1 and second electrode pattern 2. First sealing portion 61 is in contact with each of insulation layer 4, first step portion 31, second step portion 32, first body portion 21, and second body portion 22.

The thickness of first sealing portion 61 in the direction perpendicular to second surface 12 is defined as a sixth thickness H6. Sixth thickness H6 is, for example, equal to or smaller than first thickness H1. First sealing portion 61 is made, for example, of an epoxy resin. First sealing portion 61 may be made of a thermosetting resin such as a silicone resin or a polyimide resin.

Second sealing portion 62 is located on first sealing portion 61. Second sealing portion 62 is in contact with each of insulation layer 4, first sealing portion 61, first step portion 31, second step portion 32, first body portion 21, and second body portion 22. Second sealing portion 62 is made, for example, of a silicone resin. Second sealing portion 62 may be made of a thermosetting resin such as an epoxy resin or a polyimide resin. The material forming second sealing portion 62 may be higher in adhesiveness than the material forming first sealing portion 61.

The material forming first sealing portion 61 is lower in viscosity than the material forming second sealing portion 62. The viscosity of the material forming first sealing portion 61 means the viscosity of the material in a liquid state that is to form first sealing portion 61. Similarly, the viscosity of the material forming second sealing portion 62 means the viscosity of the material in a liquid state that is to form second sealing portion 62.

In the above-described configuration, first sealing portion 61 is located between first electrode pattern 1 and second electrode pattern 2, but first sealing portion 61 may surround each of first electrode pattern 1 and second electrode pattern 2. From a different point of view, first sealing portion 61 may cover each of first step portion 31 and second step portion 32. Second sealing portion 62 may be located apart from each of first step portion 31 and second step portion 32. Second sealing portion 62 may be located apart from each of first side surface 41 and second side surface 42.

The following describes functions and effects of semiconductor device 100 according to the third embodiment.

When the electrode pattern is excessively thick, sealing member 60 may not successfully fill the space between first electrode pattern 1 and second electrode pattern 2, so that voids may occur. This may degrade the performance of semiconductor device 100. According to semiconductor device 100 in the third embodiment, sealing member 60 includes first sealing portion 61 and second sealing portion 62, First sealing portion 61 is in contact with each of insulation layer 4, first step portion 31, and second step portion 32. The material forming first sealing portion 61 is lower in viscosity than the material forming second sealing portion 62. Thus, first sealing portion 61 also easily fills a narrow region between the electrode patterns. Thereby, occurrence of voids between sealing member 60 and insulation substrate 10 can be suppressed. As a result, the insulation reliability of semiconductor device 100 can be improved.

According to semiconductor device 100 in the third embodiment, first sealing portion 61 may be made of an epoxy resin. Second sealing portion 62 may be made of a silicone resin. In general, an epoxy resin is lower in moisture permeability than a silicone resin. Thus, absorption of moisture by insulation layer 4 can be suppressed. In general, a silicone resin is higher in heat resistance property than an epoxy resin. Thus, the heat resistance property of second sealing portion 62 can be improved. As a result, the heat resistance property of semiconductor device 100 can be improved.

Insulation layer 4 made of an organic material more easily absorbs moisture than insulation layer 4 made of ceramic does. According to semiconductor device 100 in the third embodiment, even in the case where insulation layer 4 is made of an organic material, absorption of moisture by insulation layer 4 can be suppressed.

### Modification of the Third Embodiment

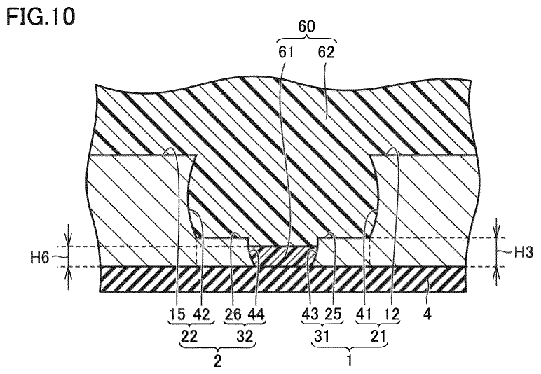

The following describes a configuration of a semiconductor device 100 according to a modification of the third embodiment with reference to FIG. 10. The schematic cross-sectional view shown in FIG. 10 corresponds to the schematic cross-sectional view shown in FIG. 9.

As shown in FIG. 10, sixth thickness H6 may be, for example, equal to or smaller than third thickness H3. The upper limit of sixth thickness H6 is not particularly limited but, for example, may be equal to or smaller than one half of third thickness H3, or may be equal to or smaller than one fourth of third thickness H3. The lower limit of sixth thickness H6 is not particularly limited but, for example, may be equal to or larger than one tenth of third thickness H3, or may be equal to or larger than one eighth of third thickness H3.

First sealing portion 61 is in contact with a part of each of first step side surface 43 and second step side surface 44. First sealing portion 61 is located apart from each of first body portion 21 and second body portion 22. First sealing portion 61 is located apart from each of first step surface 25 and second step surface 26.

A part of second sealing portion 62 is located between first electrode pattern 1 and second electrode pattern 2. Second sealing portion 62 is in contact with each of first side surface 41, second side surface 42, first step surface 25, and second step surface 26. Second sealing portion 62 is in contact with a part of each of first step side surface 43 and second step side surface 44.

The following describes functions and effects of semiconductor device 100 according to the modification of the third embodiment.

According to semiconductor device 100 in the modification of the third embodiment, sixth thickness H6 may be, for example, equal to or smaller than third thickness H3. Thus, second sealing portion 62 fills a space between the electrode patterns. Thereby, an anchor effect is exerted onto second sealing portion 62 by each of first side surface 41 and second side surface 42. As a result, peeling between second sealing portion 62 and insulation substrate 10 resulting from a heat cycle can be suppressed.

### EXAMPLES

### (Preparation of Samples)

The following describes a test performed using samples. First, three semiconductor devices according to each of Samples 1 to 10 were prepared. The semiconductor devices according to Samples 1 to 5 are comparative examples. Semiconductor devices 100 according to Samples 6 to 10 are examples.

Each of semiconductor devices 100 according to Samples 1 to 10 corresponds to semiconductor device 100 according to the second embodiment. In each of semiconductor devices 100 according to Samples 1 to 10, base plate 5 was 100 mm×150 mm in dimension. Semiconductor element 9 was 10 mm×11 mm in dimension. Semiconductor element 9 and insulation substrate 10 were joined to each other with solder. The diameter of wire 8 was 0.4 mm or 0.2 mm. Wire 8 was made of aluminum. Base plate 5 and case 6 were bonded to each other with an adhesive.

The electrode patterns of semiconductor devices 100 according to Samples 1 to 10 were produced according to the method of forming an electrode pattern of semiconductor device 100 according to the first embodiment as described above. Each of semiconductor devices 100 according to Samples 1 to 5 does not include first step portion 31 and second step portion 32. Each of semiconductor devices 100 according to Samples 6 to 10 includes first step portion 31 and second step portion 32. Each of first step portion 31 and second step portion 32 of each of semiconductor devices 100 according to Samples 6 to 10 had a thickness of 0.2 mm.

The electrode thickness (first thickness H1 and second thickness H2) of each of the semiconductor devices according to Samples 1 and 6 was 0.3 mm. The electrode thickness of each of the semiconductor devices according to Samples 2 and 7 was 0.5 mm. The electrode thickness of each of the semiconductor devices according to Samples 3 and 8 was 0.8 mm. The electrode thickness of each of the semiconductor devices according to Samples 4 and 9 was 1 mm. The electrode thickness of each of the semiconductor devices according to Samples 5 and 10 was 2 mm.

### Experiment Method

A heat cycle test was performed on each of semiconductor devices 100 according to Samples 1 to 10. First, the dielectric withstand voltage of each of semiconductor devices 100 was evaluated before a heat cycle was applied. When evaluating the dielectric withstand voltage, a voltage having an effective value of 4 kV was applied to each of semiconductor devices 100. Among three semiconductor devices 100, the number of semiconductor devices 100 having undergone dielectric breakdown was checked.

Then, each semiconductor device 100 was placed in a thermostatic bath whose temperature was controllable, and then, the temperature of the thermostatic bath was repeatedly changed between −40° C. and 180° C. In this case, assuming that a step of keeping the temperature of the thermostatic bath at −40° C. for 30 minutes and then keeping the temperature at 180° C. for 30 minutes was set as one cycle, this step was repeated 1000 cycles. The dielectric withstand voltage of each semiconductor device 100 was evaluated every 250 cycles.

### Experimental Results

TABLE 1

| | | Electrode | | | | |
|---|---|---|---|---|---|---|
| | Presence/Absence | Thickness | Number of Heat Cycles | | | |
| | of Step Portion | [mm] | 0 | 250 | 500 | 1000 |
| Sample 1 | Absent | 0.3 | A | A | A | A |
| Sample 2 | Absent | 0.5 | A | A | A | B |
| Sample 3 | Absent | 0.8 | A | B | B | C |
| Sample 4 | Absent | 1 | A | B | B | C |
| Sample 5 | Absent | 2 | A | C | C | C |
| Sample 6 | Present | 0.3 | A | A | A | A |
| Sample 7 | Present | 0.5 | A | A | A | A |
| Sample 8 | Present | 0.8 | A | A | A | A |
| Sample 9 | Present | 1 | A | A | A | A |
| Sample 10 | Present | 2 | A | A | B | B |

Table 1 shows the results of the evaluation of the dielectric withstand voltage of each of semiconductor devices 100 according to Samples 1 to 10. In Table 1, A indicates that the number of semiconductor devices 100 having undergone dielectric breakdown was zero. B indicates that the number of semiconductor devices 100 having undergone dielectric breakdown was one or two. C indicates that the number of semiconductor devices 100 having undergone dielectric breakdown was three.

As shown in Table 1, in semiconductor devices 100 according to each of Samples 2 to 5, the dielectric withstand voltage evaluation after 1000 cycles showed that there were semiconductor devices 100 having undergone dielectric breakdown. In other words, in each of semiconductor devices 100 in the comparative examples, the insulation performance was degraded by the heat cycle test in the case where the electrode thickness was 0.5 mm or more.

As shown in Table 1, in semiconductor devices 100 according to each of Samples 6 to 9, the dielectric withstand voltage evaluation after 1000 cycles showed that there was no semiconductor device 100 having undergone dielectric breakdown. In other words, in each of semiconductor devices 100 in the examples, the insulation performance was not degraded by the heat cycle test in the case where the electrode thickness was 1 mm or less.

As shown in Table 1, in each of semiconductor devices 100 according to Sample 5, the dielectric withstand voltage evaluation after 1000 cycles showed that all of semiconductor devices 100 had undergone dielectric breakdown. On the other hand, in each of semiconductor devices 100 according to Sample 10, the dielectric withstand voltage evaluation after 1000 cycles showed that only one semiconductor device 100 had undergone dielectric breakdown

Based on the above-described results, it was confirmed that the degradation in insulation performance of semiconductor device 100 resulting from application of a heat cycle could be suppressed more in semiconductor devices 100 of the examples than in semiconductor devices 100 of the comparative examples.

It should be understood that the embodiments and the examples disclosed herein are illustrative and non-restrictive in every respect. The scope of the present disclosure is defined by the terms of the claims, rather than the description above, and is intended to include any modifications within the meaning and scope equivalent to the terms of the claims.

### REFERENCE SIGNS LIST

1 first electrode pattern, 2 second electrode pattern, 3 third electrode pattern, 4 insulation layer, 5 base plate, 6 case, 7 terminal, 8 wire, 9 semiconductor element, 10 insulation substrate, 11 first surface, 12 second surface, 13 third surface, 14 fourth surface, 15 fifth surface, 16 sixth surface, 17 seventh surface, 18 eighth surface, 19 ninth surface, 20 tenth surface, 21 first body portion, 22 second body portion, 25 first step surface, 26 second step surface, 31 first step portion, 32 second step portion, 41 first side surface, 42 second side surface, 43 first step side surface, 44 second step side surface, 51 first joining portion, 52 second joining portion, 60 sealing member, 61 first sealing portion, 62 second sealing portion, 70 lid, 71 first line segment, 72 second line segment, 73 third line segment, 74 fourth line segment, 75 fifth line segment, 81 first intermediate point, 82 second intermediate point, 86 eleventh surface, 87 twelfth surface, 90 metal plate, 91 first boundary, 92 second boundary, 93 third boundary, 94 fourth boundary, 96 etching resist, 97 bottom surface, 98 wall surface, 99 groove, 100 semiconductor device, D1 first length, D2 second length, D3 third length, D4 fourth length, D5 fifth length, H1 first thickness, H2 second thickness, H3 third thickness, H4 fourth thickness, H5 fifth thickness, H6 sixth thickness.

1. A semiconductor device comprising:
an insulation substrate including an insulation layer and a first electrode pattern provided on the insulation layer;
a semiconductor element provided on the first electrode pattern;
a case surrounding the insulation substrate; and
a sealing member covering each of the insulation substrate and the semiconductor element, wherein
the first electrode pattern includes a first body portion and a first step portion protruding from the first body portion,
the first body portion has
a first surface facing the insulation layer,
a second surface located opposite to the first surface and facing the semiconductor element, and
a first side surface contiguous to the second surface,
the first step portion has
a third surface contiguous to the first surface and facing the insulation layer, and
a first step surface located opposite to the third surface and contiguous to the first side surface,
in a cross section perpendicular to the second surface, the first side surface has a curved shape,
in the cross section perpendicular to the second surface,
a boundary between the second surface and the first side surface is defined as a first boundary,
a boundary between the first side surface and the first step surface is defined as a second boundary, and
a length of a line segment connecting the first boundary and the second boundary is defined as a first length,
a length of the first side surface in the cross section perpendicular to the second surface is longer than the first length, and
the first step surface has a planar shape.

2. The semiconductor device according to claim 1, wherein
the insulation substrate further includes a second electrode pattern provided on the insulation layer and located apart from the first electrode pattern,
the second electrode pattern includes a second body portion and a second step portion protruding from the second body portion,
the second body portion has
a fourth surface facing the insulation layer,
a fifth surface located opposite to the fourth surface, and
a second side surface contiguous to the fifth surface and facing the first side surface,
the second step portion has
a sixth surface contiguous to the fourth surface and facing the insulation layer, and
a second step surface located opposite to the sixth surface and contiguous to the second side surface,
in the cross section perpendicular to the second surface,
a boundary between the fifth surface and the second side surface is defined as a third boundary,
a boundary between the second side surface and the second step surface is defined as a fourth boundary,
a length of a line segment connecting the first boundary and the third boundary is defined as a second length,
a length of a line segment connecting the second boundary and the fourth boundary is defined as a third length, and
a length of a line segment connecting an intermediate point of the first side surface and an intermediate point of the second side surface is defined as a fourth length, and
the fourth length is longer than each of the second length and the third length.

3. The semiconductor device according to claim 2, wherein
the sealing member includes
a first sealing portion in contact with each of the insulation layer, the first step portion, and the second step portion, and
a second sealing portion located on the first sealing portion.

4. The semiconductor device according to claim 3, wherein, in a direction perpendicular to the second surface, a thickness of the first sealing portion is equal to or smaller than a thickness of the first step portion.

5. (canceled)

6. The semiconductor device according to claim 3, wherein
the first sealing portion is made of an epoxy resin, and
the second sealing portion is made of a silicone resin.

7. The semiconductor device according to claim 1, wherein the insulation layer is made of an organic material.

8. The semiconductor device according to claim 1, wherein, in a direction perpendicular to the second surface, a thickness of the first electrode pattern is four times or more as large as a thickness of the insulation layer.

9. The semiconductor device according to claim 1, wherein, in a direction perpendicular to the second surface, a thickness of the first step portion is equal to or larger than one half of a thickness of the insulation layer.
